(19) United States
(12) Patent Application Publication
(10) Pub. No.: US 2006/0032848 A1
(43) Pub. Date: Feb. 16, 2006

(54) Process and system for heating semiconductor substrates in a processing chamber containing a susceptor

(76) Inventors: Young Jai Lee, Sunnyvale, CA (US); Ronald L. Wang, Salem, OR (US); Steven Ly, San Jose, CA (US); Daniel J. Devine, Los Gatos, CA (US)

Correspondence Address: DORITY & MANNING, P.A., POST OFFICE BOX 1449, GREENVILLE, SC, 29602-1449, US

(21) Appl. No.: 11/253,271

(22) Filed: Oct. 18, 2005

Related U.S. Application Data
(62) Division of application No. 10/141,515, filed on May 7, 2002, now abandoned.

(51) Int. Cl. H05B 6/02; C23C 16/00

(52) U.S. Cl. 219/600; 118/725

(57) ABSTRACT

A process and system for heating semiconductor substrates in a processing chamber on a susceptor as disclosed. In accordance with the present invention, the susceptor includes a support structure made from a material having a relatively low thermal conductivity for suspending the wafer over the susceptor. The support structure has a particular height that inhibits or prevents radial temperature gradients from forming in the wafer during high temperature processing. If needed, recesses can be formed in the susceptor for locating and positioning a support structure. The susceptor can include a wafer supporting surface defining a pocket that has a shape configured to conform to the shape of a wafer during a heat cycle.

### BACKGROUND OF THE INVENTION

During the manufacture of integrated circuits and other electrical devices, semiconductor wafers are typically placed in a thermal processing chamber and heated. During heating, various chemical and physical processes can take place. For instance, during heating cycles, the semiconductor wafers can be annealed or various coatings and films can be deposited onto the wafers.

One manner in which wafers are heated in processing chambers, particularly during epitaxial processes, is to place the wafers on heated susceptors. The susceptors can be heated, for instance, using an inductive heating device or an electrical resistance heater. In many systems containing a susceptor, the process chamber walls are kept at a lower temperature than the susceptor in order to avoid any deposits on the walls that would create any unwanted particles or contamination during the heating process. These types of processing chambers are referred to as “cold wall chambers” and operate in a thermal non-equilibrium state.

Referring to FIG. 1, a diagram of a cold wall processing chamber generally 10 is shown. The processing chamber 10 includes walls 12 that can be made from a thermal insulator and can also be actively cooled. Inside the chamber 10 is a susceptor 14 made, for instance, from silicon carbide. In this embodiment, the susceptor 14 is heated by a coil 16.

In the embodiment illustrated in FIG. 1, the processing chamber 10 is configured to handle multiple semiconductor wafers at a time. As shown, a number of wafers 18 are located within pockets 20 located on top of the susceptor 14. A process gas 22 is circulated throughout the chamber.

During processing, the semiconductor wafers 18 can be heated to temperatures of from about 1000° C. to about 1200° C. by the susceptor. Process gases, such as an inert gas, or a gas configured to react with a semiconductor wafer are introduced into the reactor during or after the wafer is heated.

In the system illustrated in FIG. 1, the wafers 18 are heated from the susceptor mostly by conduction. During heating, however, the wafers lose heat to the surrounding chamber wall 12 by radiation, due to the temperature differences between the water and process gas. Further, a small amount of heat is also transferred to the process gas from the wafers. Because of the heat passing through the wafer, a temperature gradient develops through the wafer thickness. The temperature gradient can induce the wafer to bend and deform.

During these processes, it is generally unfavorable to place the wafer on a flat surface. In particular, during bending, the wafer will only contact the susceptor at the center causing an increase in temperature at the center of the wafer and creating a radial temperature gradient in the wafer. The radial temperature gradient in the wafer can induce thermal stress in the wafer, which can cause dislocations to nucleate at defect centers. The stress generated dislocations move in large numbers along favored crystallographic planes and directions, leaving behind visible slip lines where one part of the crystal surface is displaced from another by a vertical step. This phenomenon is generally referred to as “slip”.

A number of methods have been suggested in the past to reduce the slip on wafers during processing. For instance, in the past, the surface of the susceptor has been provided with a shallow depression to form a pocket under the wafer to match the possible bending curvature of the wafer during heating. It is difficult, however, to design and manufacture a pocket where the wafer contacts the susceptor uniformly. Any misalignment can cause radial temperature gradients and slip.

In another embodiment, susceptors have been designed with pockets that are designed to have a depth greater than any possible bend of the wafer. In this embodiment, as the wafer is heated, the wafer is supported solely at its edges by the edge of the susceptor pocket and does not contact the pocket in any other location. Since the wafer touches the susceptor at the edge, the edge of the wafer can increase in temperature in relation to the center of the wafer and form radial temperature gradients. This technique, however, has been used with some success for wafers with a diameter smaller than 8 inches. Wafers having a larger diameter, however, tend to form larger radial temperature gradients and thus form more slip.

In view of the above, a need currently exists for a system and method for heating semiconductor wafers on a susceptor in a thermal processing chamber. More particularly, a need currently exists for a susceptor design that can support and heat a wafer in a thermal processing chamber and that can accommodate for wafer bending, while at the same time can heat the wafer uniformly. Such a system would be particularly useful for larger wafers, having a diameter of 6 inches or greater.

### SUMMARY OF THE INVENTION

The present invention recognizes and addresses the foregoing disadvantageous and others of prior art constructions and methods.

In general, the present invention is directed to a process and system for heating semiconductor wafers with a susceptor in thermal processing chambers. According to the present invention, the susceptor includes a support structure for supporting a wafer on the susceptor. The support structure reduces radial temperature gradients that can form in the wafer during heating and processing, such as during annealing, during depositing, or during epitaxial processes. By reducing radial temperature gradients in the wafer, slip created in the wafers can be eliminated or minimized. Also, since the wafer is heated more uniformly, the system and process of the present invention will also improve the deposit uniformity on the wafer during coating processes.

For instance, in one embodiment, the present invention is directed to a system for processing semiconductor substrates that includes a processing chamber. A susceptor is positioned within the processing chamber. The susceptor is placed in operative association with a heating device, such as an inductive heating device or an electrical resistance heater, for heating semiconductor wafers contained in the chamber. The susceptor further includes a wafer support surface for receiving a semiconductor wafer. The wafer support surface includes at least one recess and a corresponding support structure positioned within the recess. The support structure is configured to elevate a semiconductor wafer above the susceptor during thermal processing of the wafer.

In accordance with the present invention, the support structure has a thermal conductivity of no greater than about 0.06 Cal/cm-s-° C. at a temperature of 1100° C. For instance, the support structure can be made from quartz, sapphire or diamond.

For many applications, the processing chamber can be a cold wall chamber. The inductive heater used to heat the susceptor can be, for instance, a graphite element surrounded by silicon carbide.

In order to accommodate wafer bending during thermal processing, the wafer support surface of the susceptor can include a pocket having a shape configured to permit the semiconductor wafer to bend during heating without the wafer touching the top surface of the pocket. For example, the pocket can be shaped such that the top surface of the pocket is spaced from about 1 mil to about 20 mil from the semiconductor wafer at the highest processing temperature. Further, the pocket can also be shaped such that, at the highest processing temperature, the space between the wafer and the top surface of the pocket is substantially uniform and varies by no more than about 2 mil.

As described above, the support structure elevates the semiconductor wafer above the surface of the susceptor. The height of the support structure can be calculated so that heat flow through the semiconductor wafer at the highest processing chamber is uniform. In general, the support height can be within about 5% of a distance calculated as follows:

$$\frac{( {d}_{g} ) ( {k}_{s} )}{( {k}_{g} )}$$

wherein d_{g} is the distance between the susceptor and a semiconductor wafer, kₛ is the thermal conductivity of the support structure and k_{g} equals the thermal conductivity of gases present in the processing chamber.

The support structure used in the present invention can have various forms and shapes. For example, in one embodiment, the support structure can comprise a plurality of pins that are positioned in a corresponding plurality of recesses. The pins can be spaced along a common radius for supporting the semiconductor wafer. Alternatively, the support structure can comprise a ring that is placed in a trench-shaped recess. For most applications, the support structure can have a height of from about 0.02 inches to about 0.1 inches. The depth of the recess, on the other hand, can be from about 0.01 inches to about 0.08 inches.

The support structure can support the semiconductor wafer near the edges of the wafer. Alternatively, the support structure can support the wafer near the center of mass of the wafer. The system of the present invention can process semiconductor wafers of any size and shape. The system, however, is particularly well suited to uniformly heating semiconductor wafers having a diameter of 6 inches or greater. Such wafers can be heated without a significant amount of slip formation.

During the process of the present invention, the semiconductor wafers can be heated to temperatures of at least 800° C., particularly at least 1000° C., and more particularly at least 100° C. In accordance with the present invention, wafers can be heated to the maximum processing temperature such that there is no more than about 5° C. temperature difference over a radial distance of the wafer. By heating the wafers uniformly, it is possible to deposit films and coatings on the wafer uniformly. Other features, aspects and advantages of the present invention will be discussed in greater detail below.

### BRIEF DESCRIPTION OF THE DRAWINGS

A full and enabling disclosure of the present invention, including the best mode thereof, to one of ordinary skill in the art, is set forth more particularly in the remainder of the specification, including reference to the accompanying figures, in which:

FIG. 1 is a side view of a prior art thermal processing chamber;

FIG. 2 is a side view with cut away portions of one embodiment of a susceptor made in accordance with the present invention for use in thermal processing chambers, such as those illustrated in FIG. 1;

FIG. 3 is a side view of one embodiment of a support structure made in accordance with the present invention;

FIG. 4A through FIG. 4C are side views of different embodiments of support structures made in accordance with the present invention;

FIG. 5 is a perspective view of one embodiment of a ring-shaped support structure made in accordance with the present invention;

FIG. 6 is a top view of another embodiment of a susceptor made in accordance with the present invention; and

FIG. 7 is a top view of still another embodiment of a susceptor made in accordance with the present invention.

Repeated use of reference characters in the present specification and drawings is intended to represent the same or analogous features or elements of the invention.

### DETAILED DESCRIPTION

It is to be understood by one of ordinary skill in the art that the present discussion is a description of exemplary embodiments only, and is not intended to limit the broader aspects of the present invention, which broader aspects are embodied in the exemplary construction.

In general the present invention is directed to a system and process for more uniformly heating semiconductor wafers on a susceptor in thermal processing chambers. According to the present invention, semiconductor wafers can be heated on susceptors while reducing or eliminating radial temperature gradients that can cause slip or other wafer defects. According to the present invention, a semiconductor wafer is suspended above a heated susceptor using a support structure made from a relatively low conductive material, such as quartz. The support structure can be in any desired shape, such as in the form of pins, a ring, arc-shaped sections, and the like. The support structure can be placed in matching recesses formed in a susceptor surface. The recesses can be located in any possible combination at selected places under the wafer.

In accordance with the present invention, the recess depth and the height of the support structure are configured such that the resistance to heat transfer through the support structure is close to or substantially the same as the heat transfer through the space or gap between the wafer and the surface of the susceptor. In this manner, during heating, the wafer temperature just above the support structure remains substantially the same as the remainder of the bottom surface of the wafer, thus eliminating radial temperature gradients.

The actual design of the system of the present invention, such as the depth of the recess in the susceptor or the height of the support structure, will be dependent upon operating conditions, such as the operating temperature ranges, the types of gases in the chamber, and the materials used to form the support structure.

In one embodiment, the support structure suspends the semiconductor wafer above a pocket formed into the surface of the susceptor. The pocket can have a shape that substantially matches the shape of the semiconductor wafer during heating, if the wafer is heated to a temperature sufficient to cause the wafer to bend. Matching the slope of the susceptor pocket to the bending slope of the wafer can further assist in maintaining radial temperature uniformity during the heating process. Maintaining radial temperature uniformity reduces or eliminates slip in the wafer and improves the deposit uniformity during the formation of coatings on the wafer.

The process and system of the present invention are particularly well suited for use in cold wall processing chambers. It should be understood, however, that the system and process of the present invention can also be used in various other types of chambers. Further, the system and process of the present invention can be used during any type of wafer heating process, such as during annealing or during epitaxial processes.

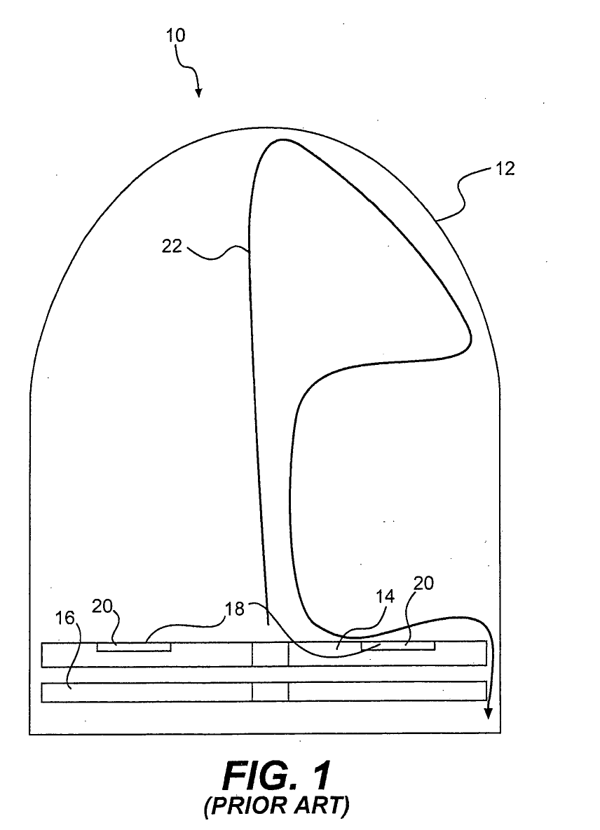

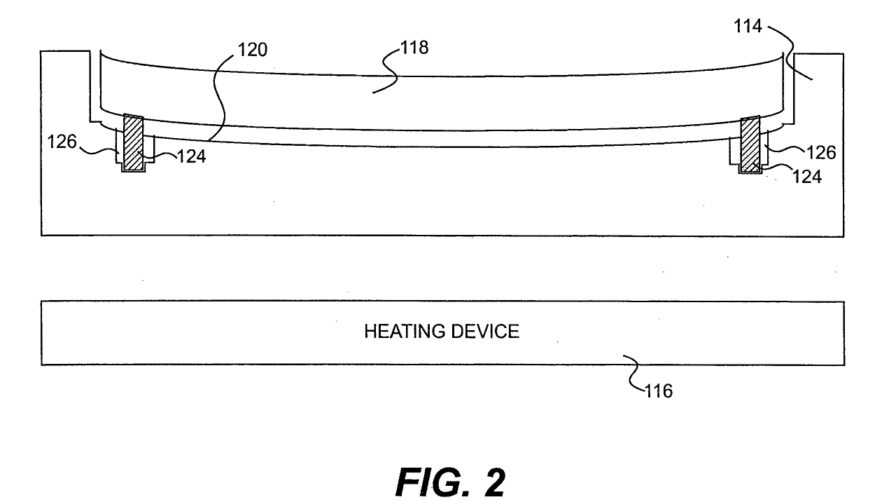

Referring to FIG. 2, one embodiment of a susceptor generally 114 made in accordance with the present invention is illustrated. Susceptor 114 is designed to be placed in a processing chamber, such as the processing chamber illustrated in FIG. 1.

As shown in FIG. 2, the susceptor 114 is placed in operative association with a heating device 116 for heating the semiconductor wafers. The heating device can be any suitable heater, such as a radio frequency induction coil. Alternatively, the susceptor can be heated by an electrical resistance heater. In one embodiment, for instance, the heating device is an inductive heater that includes a graphite element surrounded by silicon carbide. The heating device 116 can be integrated into the portion of the susceptor designed to hold semiconductor wafers or, alternatively, can heat the surface of the susceptor in a spaced apart relationship.

As is illustrated in FIG. 2, the susceptor 114 includes a pocket 120 for receiving a semiconductor wafer 118. In accordance with the present invention, the wafer 118 is positioned on a support structure 124. The support structure 124 is positioned within at least one recess 126. As shown, the support structure 124 is anchored within the bottom of the recess 126. In general, however, the interior walls of the recess 126 are in a non-contacting relationship with the support structure 124 to prevent direct heat transfer between the susceptor 114 and the support structure.

The purpose of the support structure 124 is to suspend the wafer 118 above the top surface of the pocket 120 and to assist in heating the wafer more uniformly so that there are no significant radial temperature gradients. As described above, especially in cold wall processing chambers, the semiconductor wafer 118 can lose heat to a surrounding chamber wall by radiation. Due to heat transfer through the wafer, a temperature gradient develops through the wafer thickness. The purpose of the system and process of the present invention is to permit heat transfer through the thickness of the wafer without the development or creation of radial temperature gradients. The tendency of radial temperature gradients to develop in wafers heated according to the present invention is reduced due to the use of the support structure 124. In general, the support structure 124 maintains the bottom surface of the wafer at substantially the same temperature during the heating cycle, which prevents the formation of radial temperature gradients.

In order to promote wafer temperature uniformity on the susceptor, ideally, the support structure has a conductivity substantially the same as any gases present between the surfaces of the susceptor and the bottom surface of the wafer. Unfortunately, however, no solid materials exist that have a conductively equal to that of a gas. The conductivity of the solid material is always higher. According to the present invention, however, it has been discovered by the present inventors that by using a material for the support structure that has a conductivity much lower than that of the material used to form the susceptor and by providing the support structure with a particular height in a recess formed in the susceptor, temperature uniformity in the wafer can be maintained.

For example, by setting the thermal resistance through the support structure equal to the thermal resistance through the susceptor and process gas, the following equation is obtained:
(T_{g1}−T_{w})kₛ/dₛ=(1/(dᵣ/Kₛᵤ+d_{g}/k_{g}))(T_{g1}−T_{w})+σ*(1/(1/εₛ+1/ε_{w}−1))(T_{g2}⁴−T_{w}⁴)

where,

kₛ—Conductivity of support structure

dₛ—Height of support structure

kₛᵤ—Conductivity of susceptor

dᵣ—Height of recess

k_{g}—Conductivity of process gas

d_{g}—Distance between wafer and susceptor

T_{g1}—Susceptor temperature at the bottom of recess,

T_{g2}—Susceptor top surface temperature,

T_{w}—Wafer bottom surface temperature, σ—Stefan-Boltzmann constant,

εₛ—Emissivity of susceptor

ε_{w}—Emissivity of wafer

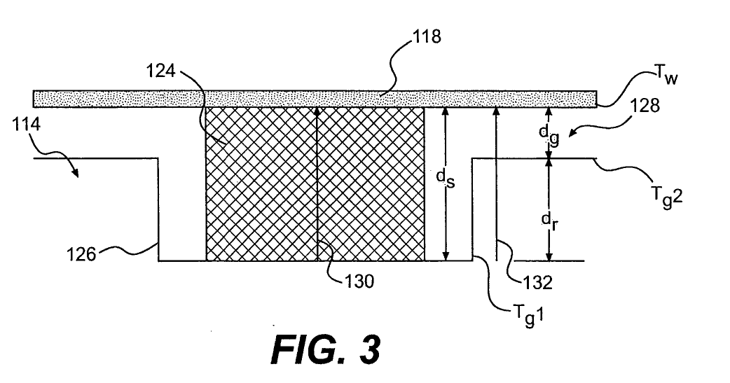

Referring to FIG. 3, an enlarged view of the support structure 124 is shown supporting the wafer 118 over the susceptor 114. As illustrated, the support structure 124 is positioned within the recess 126. The support structure 124 sits within the recess 126 without contacting the interior walls of the recess.

FIG. 3 illustrates the various distances and parameters used in the above equation. As described above, the above equation is intended to represent the situation where the heat flux through the support structure 130 is equal to the heat flux through the susceptor and through the gap between the susceptor and the wafer 132. In FIG. 3, a process gas 128 is present in the space between the wafer and the susceptor.

According to the present invention, if the conductivity of the support structure 124 is much lower than that of the susceptor 114 (kₛ<<kₛᵤ) and the radiation energy between the wafer and the susceptor is negligible, the above equation can be simplified to:

$$\frac{{d}_{s}}{{k}_{s}} = \frac{{d}_{g}}{{k}_{g}} ; or {d}_{s} = \frac{( {d}_{g} ) ( {K}_{s} )}{{k}_{g}}$$

The above simplification is particularly applicable when the susceptor is made from a material having a high heat conductivity, such as graphite or silicon carbide. As shown above, when this is the case, the height of the support structure is equal to the distance between the wafer and the susceptor multiplied by the ratio of the conductivity of the support structure to the conductivity of the process gas.

When constructing a susceptor in accordance with the present invention, it is generally desirable to have the height of the support structure as close as possible to the above calculated distance. Acceptable results, however, are achieved if the height of the support structure is within about 25% of the above calculated distance, particularly within about 10% of the above calculated distance, and more particularly within about 5% of the above calculated distance.

The actual height of the support structure 124 used in the present invention will vary depending upon numerous factors. Such factors include the material used to construct the support structure, the conductivity of the process gas, the distance between the wafer and the susceptor, the process temperatures, and the like. In general, the height of the support structure 124 can, in one embodiment, be from about 0.02 inches to about 0.1 inches, and particularly from about 0.03 inches to about 0.08 inches. At these heights, the depth of the recess 126 can be from about 0.01 inches to about 0.08 inches, and particularly from about 0.02 inches to about 0.05 inches. The presence of the recess in the susceptor allows for a particular support structure height while still maintaining the wafer as close as desired to the top surface of the susceptor.

For example, during heating cycles, the wafer 118 should be spaced from the top surface of the susceptor a distance of from about 1 mil to about 20 mil, and particularly from about 5 mil to about 11 mil. In one embodiment, the surface of the susceptor forms a pocket 120 for receiving the wafer. In one preferred embodiment, the top surface of the pocket has a shape that generally conforms to the shape of the wafer at the highest processing temperature. For example, if at the highest processing temperature the wafer tends to bend, the top surface of the pocket 120 should conform to the bend in the wafer. Better temperature uniformity throughout the wafer is maintained by maintaining a uniform distance between the susceptor and the wafer without the wafer contacting the susceptor. Ideally, at the highest processing temperature, the distance between the top surface of the pocket 120 and the bottom surface of the wafer 118 should vary by no more than about 2 mil, particularly no more than about 1 mil.

It is believed that various materials can be used to form the support structure 124 in accordance with the present invention. In general, the material chosen to form the support structure should have a relatively low thermal conductivity at higher temperatures and should not contaminate the processing chamber when heated. For instance, the material used to form the support structure should not form a metal gas at temperatures to which the wafers are heated.

In general, the thermal conductivity of the support structure can be less than about 0.06 cal/cm-s-° C., and can be particularly from about 0.0037 cal/cm-s-° C., to about 0.06 al/cm-s-° C. at temperatures of about 1100° C. or higher. Particular materials well suited for use in the present invention include quartz, sapphire, or diamond.

Through the system and process of the present invention, wafers can be heated very efficiently on heated susceptors in thermal processing chambers without significant radial temperature gradients. For example, it is believed that wafers can be processed according to the present invention so as to have no greater than a 10° C. temperature difference in the radial direction, particularly no greater than about a 5° C. temperature difference, and, in one embodiment, no greater than about a 3° C. temperature difference in the radical direction.

As described above, the support structure 124 is generally located in a recess formed into a susceptor 114. The support structure 124 should be spaced a determined distance from the interior walls of the recess when positioned within the recess. The support structure, however, should also remain in position once placed in the recess.

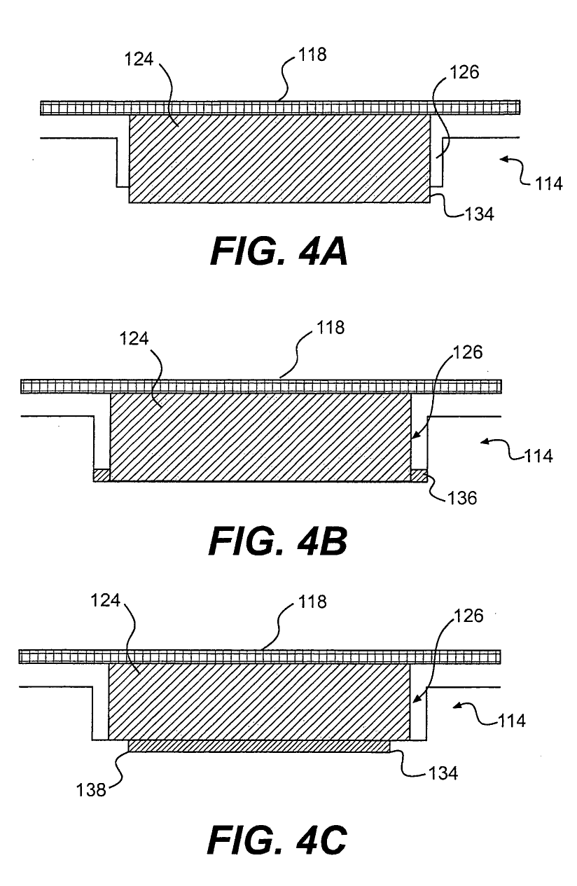

Referring to FIGS. 4A through 4C, various embodiments are shown of support structure and recess constructions.

For example, as shown in FIG. 4A, the support structure 124 generally has a uniform width or diameter. The recess 126, however, includes an indented portion 134 that is designed to maintain the support structure in a particular position.

In the embodiment illustrated in FIG. 4B, on the other hand, the support structure 124 includes a foot or tab portion 136 for maintain the support structure 124 in alignment within the recess.

Referring to FIG. 4C, another embodiment of a support structure and recess configuration is shown. In this embodiment, the recess 126 includes an indented portion 134 while the support structure 124 includes a corresponding narrow portion 138. The narrow portion 138 fits tightly within the indented portion 134.

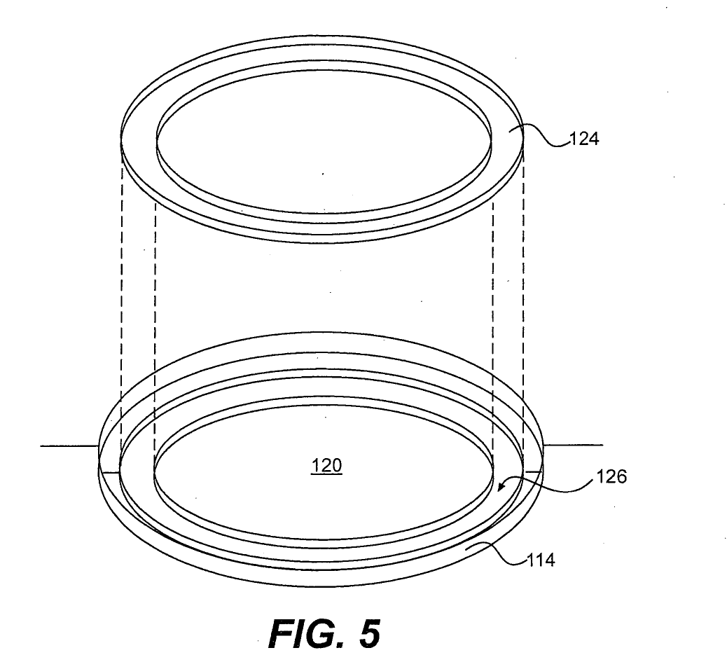

Except for its height, the size and shape of the support structure is generally independent of the mathematical equations provided above. Consequently, the support structure can be provided in any suitable shape capable of supporting a semiconductor wafer. For instance, referring to FIG. 5, in one embodiment, the support structure 124 can be in the shape of a ring. The ring 124 can fit within a recess 126 formed into the susceptor 114. In this embodiment, the recess 126 can have a trench-like shape.

In one embodiment, when the support structure is in the shape of a ring as shown in FIG. 5, the ring can have a width of about 0.25 inches and the recess can be in the shape of a trench having a width of about 0.3 inches.

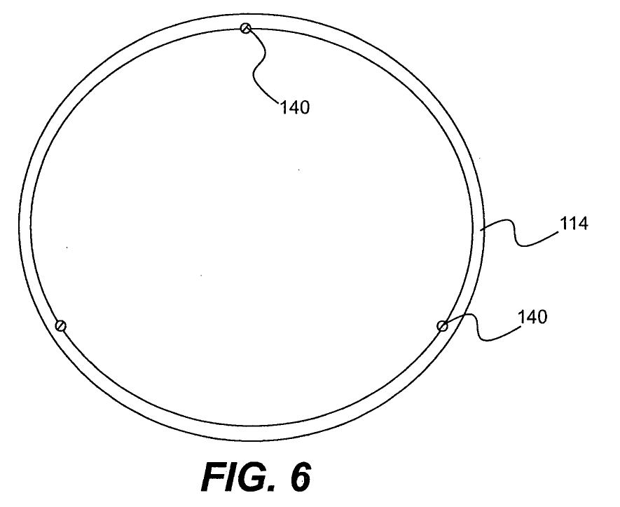

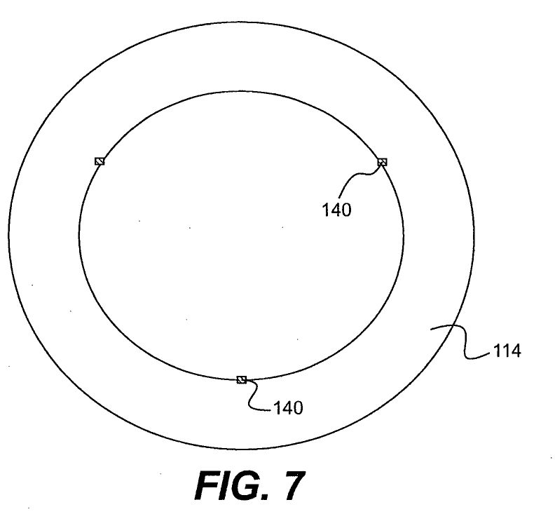

In addition to having a ring shape as shown in FIG. 5, the support structure can also be in the shape of pins 140 as shown in FIGS. 6 and 7. As shown, the pins can be spaced along a common radius for uniformly supporting a semiconductor wafer. In general, 3 or more pins are needed to support the wafer.

In the embodiment illustrated in FIG. 6, the pins 140 are positioned to support a semiconductor wafer at or near its edge. In FIG. 7, however, the pins are positioned to support a wafer near its center of mass. It should be understood, however, that the support structure can be placed at any suitable wafer radius.

The cross-sectional shape of the pins is generally not critical. For instance, in FIG. 6, the pins are shown having a cylindrical shape, while in FIG. 7 the pins have a square or rectangular shape. For exemplary purposes only, when in the shape of a cylinder, the pins can have a diameter of about 0.25 inches and can be placed in a recess having a diameter of about 0.3 inches.

The top surface of the pins 140 can be of any suitable shape for supporting a wafer. For instance, for many applications, the top surface of the pins should be flat.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

1-28. (canceled)

29. A process for uniformly heating semiconductor wafers on a heated susceptor comprising:
providing a processing chamber containing a susceptor, the susceptor being heated and defining a wafer support surface, the susceptor further comprising a support structure extending from the wafer support surface, the wafer support surface having a shape configured to permit a semiconductor wafer to bend during heating without contacting the surface, the support structure being made from a material that has a conductivity of no greater than about 0.06 Cal/cm-s-° C. at 1100° C.;
placing a semiconductor wafer on the support structure; and
heating the semiconductor wafer to a maximum processing temperature which causes the wafer to bend without contacting the wafer support surface.

30. A process as defined in claim 29, wherein the maximum processing temperature is at least 1,000° C.

31. A process as defined in claim 29, wherein the susceptor and wafer are heated by an electrical resistance heater or an inductive heater.

32. A process as defined in claim 29, wherein the support structure is made from a material comprising quartz, sapphire or diamond.

33. A process as defined in claim 29, wherein the wafer support surface is shaped such that the surface is spaced from about 1 mil to about 20 mils from the semiconductor wafer at the maximum processing temperature and such that the space between the wafer and the support surface is substantially uniform at the maximum processing temperature and varies by no more than about 2 mil.

34. A process as defined in claim 29, wherein the support structure has a height that is within 5% of a distance calculated as follows at the maximum processing temperature:
$$\frac{( {d}_{g} ) ( {k}_{s} )}{{k}_{g}}$$
wherein:
d_{g}=distance between the susceptor and a semiconductor wafer
kₛ=thermal conductivity of the support structure
k_{g}=thermal conductivity of gases present in the processing chamber.

35. A process as defined in claim 29, wherein the support structure comprises at least three support pins located along a common radius.

36. A process as defined in claim 29, wherein the support structure is in the shape of a ring.

37. A process as defined in claim 29, wherein the support structure has a height of from about 0.02 inches to about 0.1 inches.

38. A process as defined in claim 29, wherein the wafer support surface further defines a recess, the support structure being located within the recess.

39. A process as defined in claim 29, wherein the wafer is heated in a cold wall processing chamber.

40. A process as defined in claim 29, wherein the semiconductor wafer has a diameter of at least 10 inches.

41. A process as defined in claim 29, wherein the wafer is heated such that at the maximum processing temperature there is no more than about 5° C. temperature difference throughout the semiconductor wafer.
